(19) United States
(12) Patent Application Publication
(10) Pub. No.: US 2025/0098474 A1
(43) Pub. Date: Mar. 20, 2025

(54) DISPLAY APPARATUS AND METHOD OF MANUFACTURING THE SAME

(71) Applicant: Samsung Display Co., Ltd., Yongin-si (KR)

(72) Inventors: Sunkyu Joo, Yongin-si (KR); Keunchan Oh, Yongin-si (KR); Taehyung Hwang, Yongin-si (KR)

(73) Assignee: Samsung Display Co., Ltd., Yongin-si (KR)

(21) Appl. No.: 18/815,075

(22) Filed: Aug. 26, 2024

(30) Foreign Application Priority Data
Sep. 19, 2023 (KR) 10-2023-0124998

(51) Int. Cl. H10K 59/38; H10K 59/12; H10K 59/80; H10K 102/00

(52) U.S. Cl. CPC H10K 59/38; H10K 59/1201; H10K 59/8723; H10K 59/877; H10K 2102/331

(57) ABSTRACT

A display apparatus includes a first partition wall disposed on a substrate, a first color quantum dot layer spaced apart from the first partition wall in a first direction, a second partition wall disposed between the first partition wall and the first color quantum dot layer, a light-transmissive layer disposed between the first partition wall and the second partition wall, a second color quantum dot layer disposed between the second partition wall and the first color quantum dot layer, and a metal layer disposed on respective upper surfaces and respective lateral surfaces of the first partition wall and the second partition wall and a lateral surface of the first color quantum dot layer. The first partition wall, the second partition wall, and the first color quantum dot layer each include a same material.

### CROSS-REFERENCE TO RELATED APPLICATION(S)

This application claims priority to and benefits of Korean Patent Application No. 10-2023-0124998 under 35 U.S.C. § 119, filed on Sep. 19, 2023, in the Korean Intellectual Property Office, the entire contents of which are incorporated herein by reference.

### BACKGROUND

### 1. Technical Field

One or more embodiments relate to a display apparatus and a method of manufacturing the same.

### 2. Description of the Related Art

Display apparatuses visually display data. Display apparatuses are used as displays of small products, such as mobile phones, or as displays of large products, such as televisions.

A display apparatus may include a liquid crystal display device that does not emit light by itself and uses light from a backlight or a light-emitting display apparatus including a display element capable of emitting light. The display element may include an emission layer.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

One or more embodiments include a display apparatus and a method of manufacturing the display apparatus.

Additional aspects will be set forth in part in the description which follows and, in part, will be apparent from the description, or may be learned by practice of the presented embodiments.

According to one or more embodiments, a display apparatus may include a first partition wall disposed on a substrate; a first color quantum dot layer spaced apart from the first partition wall in a first direction; a second partition wall disposed between the first partition wall and the first color quantum dot layer; a light-transmissive layer disposed between the first partition wall and the second partition wall; a second color quantum dot layer disposed between the second partition wall and the first color quantum dot layer; and a metal layer disposed on respective upper surfaces and respective lateral surfaces of the first partition wall and the second partition wall and a lateral surface of the first color quantum dot layer. The first partition wall, the second partition wall, and the first color quantum dot layer include a same material.

The light-transmissive layer may include scattering particles.

The display apparatus may further include a first protective layer disposed below the metal layer.

The metal layer may not be disposed on at least a portion of the first protective layer disposed between the first partition wall and the second partition wall, at least a portion of the first protective layer disposed between the second partition wall and the first color quantum dot layer, and at least a portion of an upper surface of the first color quantum dot layer.

The display apparatus may further include a spacer disposed on at least a portion of the first color quantum dot layer.

The spacer may include a material that is the same as a material included in the light-transmissive layer.

The spacer and the second color quantum dot layer may include a material.

The display apparatus may further include a second protective layer disposed on the light-transmissive layer, the second color quantum dot layer, and the spacer.

According to one or more embodiments, a display apparatus may include a first partition wall disposed on a substrate; a light transmissive layer spaced apart from the first partition wall in a first direction; a second partition wall disposed between the first partition wall and the light transmissive layer; a first color quantum dot layer disposed between the first partition wall and the second partition wall; a second color quantum dot layer disposed between the second partition wall and the light transmissive layer; and a metal layer disposed on respective upper surfaces and respective lateral surfaces of the first partition wall and the second partition wall and a lateral surface of the light transmissive layer. The first partition wall, the second partition wall, and the light transmissive layer include a same material.

The display apparatus may further include a first protective layer disposed below the metal layer.

The display apparatus may further include a spacer disposed on at least a portion of the light transmissive layer.

The spacer and the first color quantum dot layer may include a same material.

The spacer and the second color quantum dot layer may include a same material.

According to one or more embodiments, a method of manufacturing a display apparatus may include forming a first partition wall, a second partition wall, and a first color quantum dot layer on a substrate; forming a first protective layer on the first partition wall, the second partition wall, and the first color quantum dot layer; forming a metal layer disposed on respective upper surfaces and respective lateral surfaces of the first partition wall and the second partition wall and a lateral surface of the first color quantum dot layer; forming a light transmissive layer disposed between the first partition wall and the second partition wall; forming a spacer disposed on at least a portion of the first color quantum dot layer; and forming a second color quantum dot layer disposed between the second partition wall and the first color quantum dot layer. The light transmissive layer and the spacer are formed simultaneously.

The light transmissive layer may include scattering particles.

The spacer and the light transmissive layer may include a same material.

The metal layer may not be disposed on at least a portion of the first protective layer disposed between the first partition wall and the second partition wall, at least a portion of the first protective layer disposed between the second partition wall and the first color quantum dot layer, and at least a portion of an upper surface of the first color quantum dot layer.

The forming of the first partition wall, the second partition wall, and the first color quantum dot layer on the substrate may include disposing, on the substrate, a first color quantum dot layer forming material; disposing a first photoresist on at least a portion of the first color quantum dot layer forming material; forming the first partition wall, the second partition wall, and the first color quantum dot layer by removing at least a portion of the first color quantum dot layer forming material on an upper surface of which the first photoresist is not disposed; and removing the first photoresist.

The forming of the metal layer disposed on the respective upper surfaces and the respective lateral surfaces of the first partition wall and the second partition wall and the lateral surface of the first color quantum dot layer may include continuously disposing a metal layer forming material on the first protective layer; disposing a second photoresist on at least a portion of the metal layer forming material; and forming a metal layer by removing at least a portion of the metal layer forming material from an upper surface where the second photoresist is not disposed.

The forming of the light transmissive layer and the spacer may include continuously forming a light transmissive layer forming material on the metal layer; disposing a third photoresist on at least a portion of the light transmissive layer forming material; forming the light transmissive layer and the spacer by removing at least a portion of the light transmissive layer forming material from an upper surface where the third photoresist is not disposed; and removing the third photoresist.

### BRIEF DESCRIPTION OF THE DRAWINGS

The above and other aspects, features, and advantages of the disclosure will be more apparent from the following description taken in conjunction with the accompanying drawings, in which:

FIG. 1 is a schematic perspective view of a display apparatus according to an embodiment;

FIG. 2 is a schematic cross-sectional view of pixels of the display apparatus according to an embodiment;

FIG. 3 is a magnified cross-sectional view of optical units in a color conversion-transmission layer of FIG. 2;

FIG. 4 is a schematic diagram of an equivalent circuit illustrating a light-emitting diode included in the display apparatus and a pixel circuit electrically connected to the light-emitting diode, according to an embodiment;

FIGS. 5 and 6 are schematic cross-sectional views taken along line I-I′ of FIG. 1, according to embodiments; and

FIGS. 7 through 18 are schematic cross-sectional views schematically illustrating a method of manufacturing a display apparatus, according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are described below, by referring to the figures, to explain aspects of the description.

As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, embodiments will be illustrated in the drawings and described in detail in the written description. Hereinafter, effects and features of the disclosure and a method for accomplishing them will be described more fully with reference to the accompanying drawings, in which embodiments of the disclosure are shown. The disclosure may, however, be embodied in many different forms and should not be construed as limited to the embodiments set forth herein.

One or more embodiments will be described below in more detail with reference to the accompanying drawings. Those components that are the same as or are in correspondence with each other are rendered the same reference numeral regardless of the figure number, and redundant explanations are omitted.

It will be understood that although the terms “first,” “second,” etc. may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

As used herein, the singular forms “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be further understood that the terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will be understood that when a layer, region, or component is referred to as being “formed on” another layer, region, or component, it can be directly or indirectly formed on the other layer, region, or component. For example, intervening layers, regions, or components may be present.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

Sizes of elements in the drawings may be exaggerated or reduced for convenience of explanation. For example, since sizes and thicknesses of components in the drawings are arbitrarily illustrated for convenience of explanation, embodiments are not limited thereto.

When an embodiment may be implemented differently, a specific process order may be performed differently from the described order. For example, two consecutively described processes may be performed substantially at the same time or performed in an order opposite to the described order.

In the specification, “A and/or B” represents A or B, or A and B. The expression “at least one of A and B” indicates only A, only B, both A and B, or variations thereof.

It will also be understood that when a layer, region, or component is referred to as being “connected” or “coupled” to another layer, region, or component, it can be directly connected or coupled to the other layer, region, or/and component or intervening layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

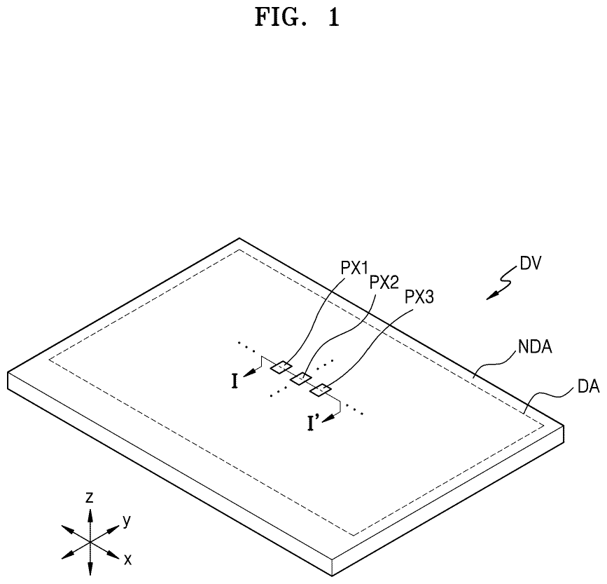

FIG. 1 is a schematic perspective view of a display apparatus DV according to an embodiment.

Referring to FIG. 1, the display apparatus DV may include a display area DA and a non-display area NDA around the display area DA. The display apparatus DV may provide an image through an array of pixels arranged or disposed in a two-dimensional (2D) manner on an x-y plane in the display area DA. The pixels may include a first pixel PX1, a second pixel PX2, and a third pixel PX3. The first pixel PX1 may be a blue pixel Pb, the second pixel PX2 may be a green pixel, and the third pixel PX3 may be a red pixel Pr.

The first pixel PX1, the second pixel PX2, and the third pixel PX3 are areas capable of emitting blue light, green light, and red light, respectively, and the display apparatus DV may provide an image by using the light emitted by pixels.

The non-display area NDA may not provide an image, and may surround the entirety of the display area DA. A driver or a main power line for providing an electrical signal or power to pixel circuits may be arranged or disposed in the non-display area NDA. Pads that may be electrically connected to an electronic device or a printed circuit board (PCB) may be included in the non-display area NDA.

The display area DA may have the shape of a polygon including a quadrangle as shown in FIG. 1. For example, the display area DA may have a rectangular shape in which a horizontal length is greater than a vertical length, a rectangular shape in which a horizontal length is less than a vertical length, or a square shape. By way of example, the display area DA may have any of various shapes such as an oval or a circle.

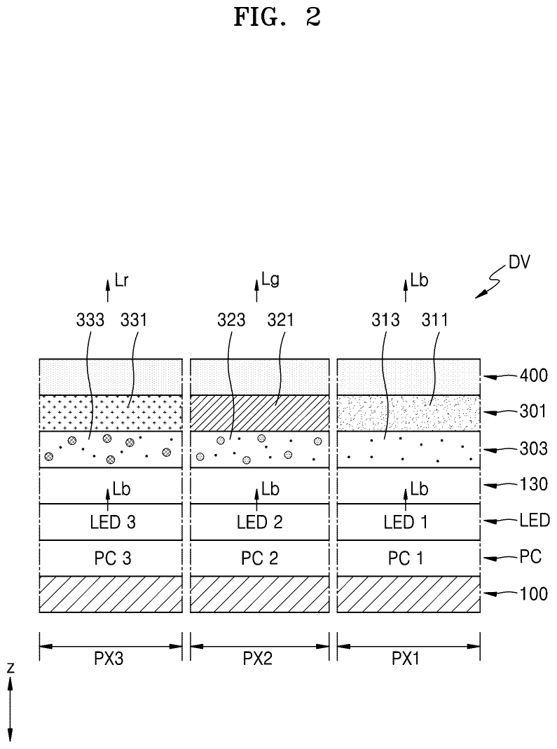

FIG. 2 is a schematic cross-sectional view of pixels of the display apparatus DV according to an embodiment.

Referring to FIG. 2, the display apparatus DV may include a circuit layer PC on a lower substrate 100. The circuit layer PC may include first, second, and third pixel circuits PC1, PC2, and PC3, and the first, second, and third pixel circuits PC1, PC2, and PC3 may be electrically connected to first, second, and third light-emitting diodes LED1, LED2, and LED3 of a light-emitting diode layer LED.

The first, second, and third light-emitting diodes LED1, LED2, and LED3 may include organic light-emitting diodes containing organic materials. By way of example, the first, second, and third light-emitting diodes LED1, LED2, and LED3 may be inorganic light-emitting diodes containing inorganic materials. The inorganic light-emitting diodes may include PN junction diodes including materials based on an inorganic material semiconductor. In case that a voltage is applied to the PN junction diodes in a forward direction, holes and electrons are injected, and energy generated by recombination of the holes and the electrons is converted into light energy to thereby emit light of a selectable color. The above-mentioned inorganic light-emitting diodes may each have a width of several to several hundreds of micrometers or several to several hundreds of nanometers. By way of example, a light emitting diode (LED) may be an LED containing quantum dots. As described above, an emission layer of the LED may include an organic material, include an inorganic material, include quantum dots, include an organic material and quantum dots, or include an inorganic material and quantum dots.

The first, second, and third light-emitting diodes LED1, LED2, and LED3 may emit light of the same color. For example, light (for example, blue light Lb) emitted from the first, second, and third light-emitting diodes LED1, LED2, and LED3 may be transmitted by a color conversion-transmission layer 303 via an encapsulation layer 130 on the light-emitting diode layer LED.

The color conversion-transmission layer 303 may include optical units that convert the color of light (for example, blue light Lb) emitted by the light-emitting diode layer LED or transmitting the light without converting the color of the light. For example, the color conversion-transmission layer 303 may include quantum dot layers 323 and 333 that convert the light (for example, blue light Lb) emitted by the light-emitting diode layer LED into light of another color, and a light-transmissive layer 313 that transmits the light (for example, blue light Lb) emitted by the light-emitting diode layer LED without color conversion. The color conversion-transmission layer 303 may include the third color quantum dot layer 333 corresponding to the red pixel Pr, the second color quantum dot layer 323 corresponding to the green pixel Pg, and the light-transmissive layer 313 corresponding to the blue pixel Pb. The third color quantum dot layer 333 may convert the blue light Lb into the red light Lr, and the second color quantum dot layer 323 may convert the blue light Lb into the green light Lg. The light-transmissive layer 313 may transmit the blue light Lb without conversion.

A color filter layer 301 may be disposed on the color conversion-transmission layer 303. The color filter layer 301 may include first, second, and third color filter layers 311, 321, and 331 of different colors. For example, the first color filter layer 311 may be a blue color filter, the second color filter layer 321 may be a green color filter, and the third color filter layer 331 may be a red color filter layer.

Each of light color-converted by the color conversion-transmission layer 303 and light transmitted thereby may have improved color purity while passing through the first, second, and third color filter layers 311, 321, and 331. The color filter layer 301 may prevent or minimize external light (for example, light incident from outside the display device DV toward the display device DV) from being reflected and visually recognized by a user.

An upper substrate 400 may be included on the color filter layer 301. The upper substrate 400 may include glass or a transparent organic material. For example, the upper substrate 400 may include a transparent organic material such as an acrylic resin.

According to an embodiment, the upper substrate 400 is a type of substrate, and, after the color filter layer 301 and the color conversion-transmission layer 303 are formed on the upper substrate 400, the color conversion-transmission layer 303 may face the encapsulation layer 130.

By way of example, the color conversion-transmission layer 303 and the color filter layer 301 may be sequentially formed on the encapsulation layer 130, and the upper substrate 400 may be formed by being directly coated the color filter layer 301 and cured. Although not shown in FIG. 2, another optical film, such as an anti-reflection (AR) film, may be disposed on the upper substrate 400.

The display apparatus DV having the above-described structure may include a television, an advertisement panel, a movie theater screen, a monitor, a tablet PC, a laptop, etc.

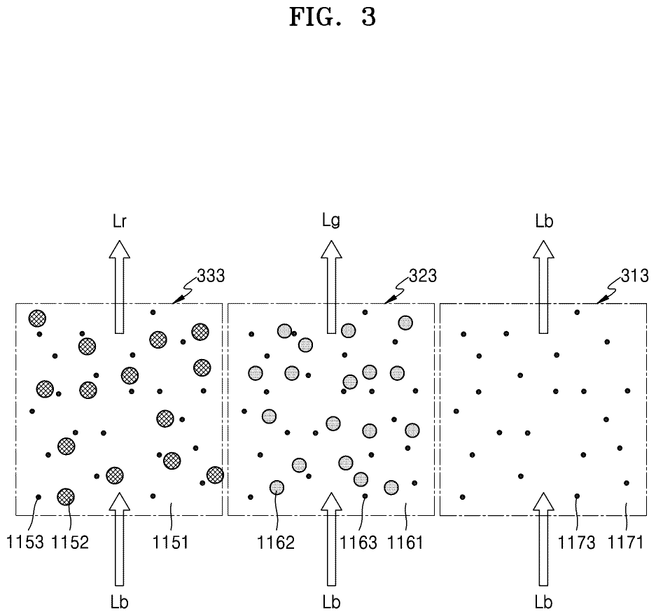

FIG. 3 is a magnified schematic cross-sectional view of the optical units of the color conversion-transmission layer 303 of FIG. 2.

Referring to FIG. 3, the third color quantum dot layer 333 may convert incident blue light Lb to the red light Lr. As shown in FIG. 3, the third color quantum dot layer 333 may include a first photosensitive polymer 1151, and first quantum dots 1152 and first scattering particles 1153 dispersed in the first photosensitive polymer 1151.

The third quantum dots 1152 may be excited by the blue light Lb and isotropically emit the red light Lr having a longer wavelength than a wavelength of the blue light Lb. The first photosensitive polymer 1151 may be an organic material having a light-transmitting property. The first scattering particles 1153 may increase color conversion efficiency by scattering the blue light Lb not absorbed by the third color quantum dots 1152 so that more third color quantum dots 1152 are excited. The first scattering particles 1153 may be, for example, titanium oxide (TiO2) or metal particles. The third quantum dots 1152 may be selected from a Group II-VI elements-containing compound, a Group III-V elements-containing compound, a Group IV-VI elements-containing compound, a Group IV element, a Group IV element-containing compound, and a combination thereof.

The second color quantum dot layer 323 may convert the incident blue light Lb to the green light Lg. As shown in FIG. 3, the second color quantum dot layer 323 may include a second photosensitive polymer 1161, and second quantum dots 1162 and second scattering particles 1163 dispersed in the second photosensitive polymer 1161.

The second color quantum dots 1162 may be excited by the blue light Lb and isotropically emit the green light Lg having a longer wavelength than the wavelength of the blue light Lb. The second photosensitive polymer 1161 may be an organic material having a light-transmitting property.

The second scattering particles 1163 may increase color conversion efficiency by scattering the blue light Lb not absorbed by the second color quantum dots 1162 so that more second color quantum dots 1162 are excited. The second scattering particles 1163 may be, for example, titanium oxide (TiO2) or metal particles. The second color quantum dots 1162 may be selected from a Group II-VI elements-containing compound, a Group III-V elements-containing compound, a Group IV-VI elements-containing compound, a Group IV element, a Group IV element-containing compound, and a combination thereof.

According to an embodiment, the third color quantum dots 1152 and the second color quantum dots 1162 may be the same materials. In this case, sizes of the third color quantum dots 1152 may be greater than those of the second color quantum dots 1162.

The light-transmissive layer 313 may transmit the blue light Lb without converting the blue light Lb incident upon the light-transmissive layer 313. As shown in FIG. 3, the light-transmissive layer 313 may include a third photosensitive polymer 1171 in which third scattering particles 1173 are dispersed. The third photosensitive polymer 1171 may be, for example, an organic material having a light transmitting property, such as silicon resin or epoxy resin, and may be the same material as the first and second photosensitive polymers 1151 and 1161. The third scattering particles 1173 may scatter and emit the blue light Lb, and may be the same material as the first and second scattering particles 1153 and 1163.

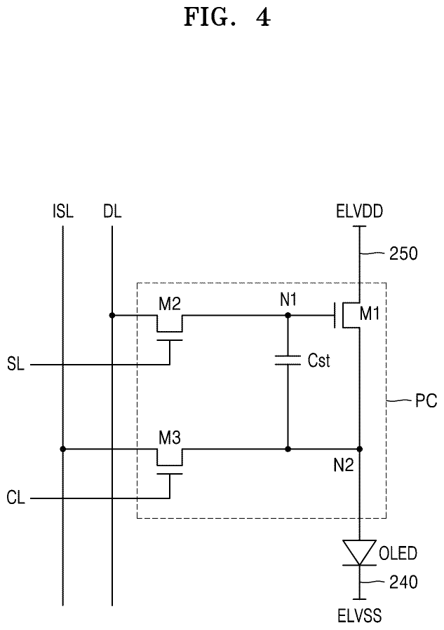

FIG. 4 is a schematic diagram of an equivalent circuit illustrating a light-emitting diode included in a display apparatus according to an embodiment and a pixel circuit electrically connected to the light-emitting diode.

Referring to FIG. 4, a first electrode (for example, an anode) of a light-emitting diode, namely, an organic light-emitting diode OLED, may be connected to a pixel circuit PC, and a second electrode (for example, a cathode) of the organic light-emitting diode OLED may be connected to a common voltage line 240 that provides a power supply voltage ELVSS. The organic light-emitting diode OLED may emit light with a brightness corresponding to the amount of current provided by the pixel circuit PC.

The organic light-emitting diode OLED in FIG. 4 may correspond to each of the first, second, and third light-emitting diodes LED1, LED2, and LED3 shown in FIG. 2, and the pixel circuit PC in FIG. 4 may correspond to each of the first, second, and third pixel circuits PC1, PC2, and PC3 shown in FIG. 2.

The pixel circuit PC may control the amount of current flowing from a driving power voltage ELVDD to the common power voltage ELVSS via the organic light-emitting diode OLED in response to a data signal. The pixel circuit PC may include a driving transistor M1, a switching transistor M2, a sensing transistor M3, and a storage capacitor Cst.

Each of the driving transistor M1, the switching transistor M2, and the sensing transistor M3 may be an oxide semiconductor thin film transistor including a semiconductor layer composed of an oxide semiconductor, or a silicon semiconductor thin film transistor including a semiconductor layer composed of polysilicon. Each of the driving transistor M1, the switching transistor M2, and the sensing transistor M3 may include a source electrode (or a source region) and a drain electrode (or a drain region).

The source electrode (or the source region) of the driving transistor M1 may be connected to a driving voltage line 250 that supplies the driving power voltage ELVDD, and the drain electrode (or the drain region) of the driving transistor M1 may be connected to the first electrode (for example, the anode) of the organic light-emitting diode OLED. A gate electrode of the driving transistor M1 may be connected to a first node N1. The driving transistor M1 may control the amount of current flowing through the organic light-emitting diode OLED according to the driving power voltage ELVDD in response to a voltage of the first node N1. However, respective locations of the source electrode (or the source region) and the drain electrode (or the drain area) may be changed.

The switching transistor M2 may be a switching transistor. The source electrode (or the source region) of the switching transistor M2 may be connected to a data line DL, and the drain electrode (or the drain region) of the switching transistor M2 may be connected to the first node N1. A gate electrode of the switching transistor M2 may be connected to a scan line SL. The switching transistor M2 may be turned on in case that a scan signal is supplied to the scan line SL, and may electrically connect the data line DL to the first node N1. However, the respective locations of the source electrode (or the source region) and the drain electrode (or the drain region) may be changed.

The sensing transistor M3 may be an initialization transistor and/or a sensing transistor. The drain electrode (or the drain region) of the sensing transistor M3 may be connected to a second node N2, and the source electrode (or the source region) thereof may be connected to a sensing line ISL. A gate electrode of the sensing transistor M3 may be connected to a control line CL. However, the respective locations of the source electrode (or the source region) and the drain electrode (or the drain region) may be changed.

The storage capacitor Cst may be connected between the first node N1 and the second node N2. For example, a first capacitor electrode of the storage capacitor Cst may be connected to the gate electrode of the driving transistor M1, and a second capacitor electrode of the storage capacitor Cst may be connected to the first electrode (for example, the anode) of the organic light-emitting diode OLED.

In FIG. 4, the driving transistor M1, the switching transistor M2, and the sensing transistor M3 are shown as NMOS, but the disclosure is not limited thereto. For example, at least one of the driving transistor M1, the switching transistor M2, and the sensing transistor M3 may be formed as PMOS.

Although three transistors are shown in FIG. 4, the disclosure is not limited thereto. The pixel circuit PC may include four or more transistors.

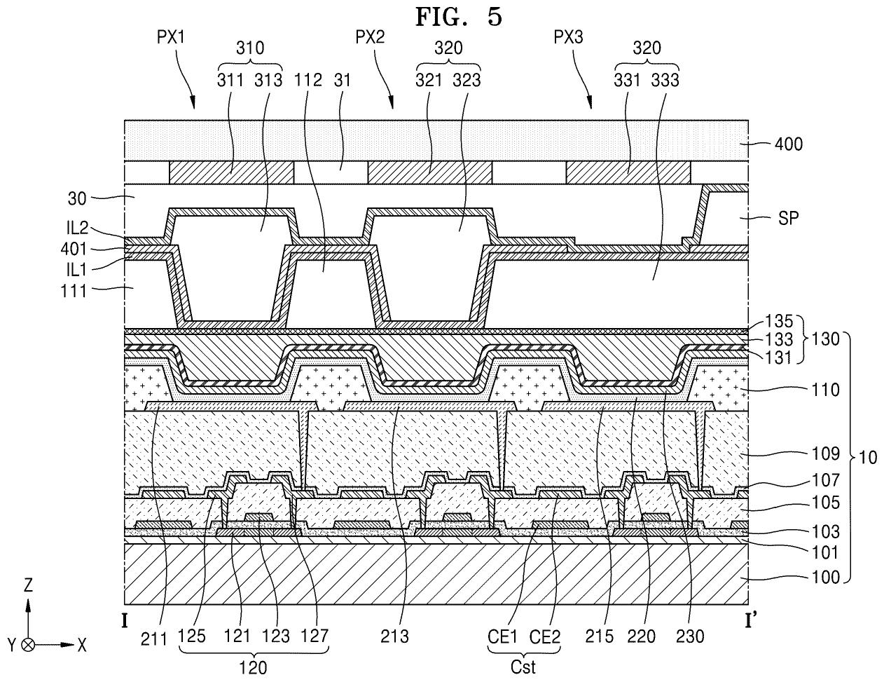

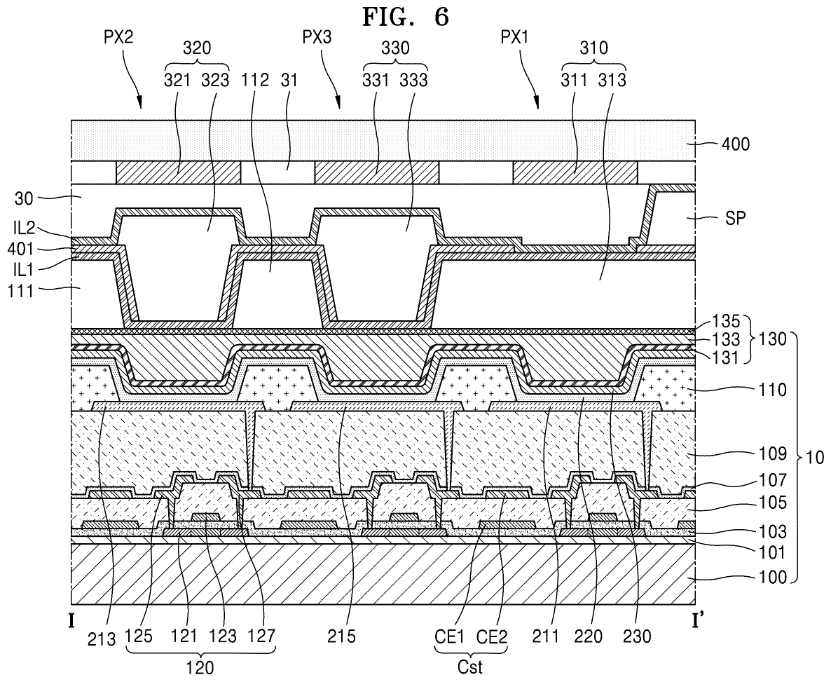

FIGS. 5 and 6 are schematic cross-sectional views taken along line I-I′ of FIG. 1, according to embodiments.

Referring to FIG. 5, the display apparatus DV according to an embodiment may include a display unit 10, quantum dot layers 323 and 333, a light transmissive layer 313, first, second, and third color filter layers 311, 321, and 331, and an adhesive layer 30.

The display unit 10 may include the lower substrate 100. The lower substrate 100 may include a glass material, a metal material, a ceramic material, or a material having flexible or bendable characteristics. In case that the lower substrate 100 is flexible or bendable, the lower substrate 100 may include a polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. The lower substrate 100 may have a single-layered or multi-layered structure composed of the above-mentioned materials. In case that the lower substrate 100 has a multi-layered structure, the lower substrate 100 may have a multi-layered structure including two layers each including a polymer resin and a barrier layer including an inorganic material (silicon oxide, silicon nitride, silicon oxynitride, or the like) between the two layers. In this way, various modifications may be made.

A buffer layer 101 may be formed on the lower substrate 100. The buffer layer 101 may include an inorganic material, such as silicon oxide, silicon nitride, and/or silicon oxynitride, and may be a single layer or a multi-layer. The buffer layer 101 may increase smoothness of an upper surface of the lower substrate 100 or prevent or minimize infiltration of impurities or moisture from the outside of the lower substrate 100 and the like into a semiconductor layer 121 of a thin-film transistor 120.

A pixel circuit may be located (or disposed) on the buffer layer 101, and a display element layer including first through third display elements electrically connected to the pixel circuit may be located over the pixel circuit. The pixel circuit may include the thin-film transistor 120 and a capacitor Cst. The first through third display elements being electrically connected to the pixel circuit may be understood as first, second, and third pixel electrodes 211, 213, and 215 of the first through third display elements being electrically connected to the thin-film transistor 120.

The thin-film transistor 120 may include a semiconductor layer 121 including amorphous silicon, polycrystalline silicon, or an organic semiconductor material, a gate electrode 123, a source electrode 125, and a drain electrode 127.

The semiconductor layer 121 may be disposed on the buffer layer 101 and may include amorphous silicon or polysilicon. For example, the semiconductor layer 121 may include oxide of at least one of indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). The semiconductor layer 121 may include Zn oxide, In—Zn oxide, Ga—In—Zn oxide, or the like as a Zn oxide-based material. The semiconductor layer 121 may be an In—Ga—Zn—O (IGZO), In—Sn—Zn—O (ITZO), or In—Ga—Sn—Zn—O (IGTZO) semiconductor containing a metal, such as In, Ga, or Sn, in ZnO. The semiconductor layer 121 may include a channel region, and a source region and a drain region located on both sides of the channel region.

The gate electrode 123 is located over the semiconductor layer 121 such as to at least partially overlap the semiconductor layer 121. The gate electrode 123 may include various conductive materials including molybdenum (Mo), aluminum (Al), copper (Cu), and titanium (Ti), and may have various layered structures. For example, the gate electrode 123 may include an Mo layer and an Al layer or may have a multi-layered structure of Mo/Al/Mo.

Similar to the gate electrode 123, each of the source electrode 125 and the drain electrode 127 may include various conductive materials including molybdenum (Mo), aluminum (Al), copper (Cu), and titanium (Ti), and may have various layered structures. For example, each of the source electrode 125 and the drain electrode 127 may include a Ti layer and an Al layer or may have a multi-layered structure of Ti/Al/Ti. The source electrode 125 and the drain electrode 127 may be connected to a source region or drain region of the semiconductor layer 121 through a contact hole.

To secure insulation between the semiconductor layer 121 and the gate electrode 123, a gate insulating layer 103 may be interposed between the semiconductor layer 121 and the gate electrode 123. The gate insulating layer 103 may include an inorganic material, such as silicon oxide, silicon nitride, and/or silicon oxynitride. A first interlayer insulating layer 105 may be located as a layer having a given dielectric constant over the gate electrode 123, and the first interlayer insulating layer 105 may include an inorganic material such as silicon oxide, silicon nitride, and/or silicon oxynitride. The source electrode 125 and the drain electrode 127 may be located on the interlayer insulating layer 105. An insulating layer including an inorganic material as described above may be formed via chemical vapor deposition (CVD) or atomic layer deposition (ALD). This is equally applied to embodiments and modifications thereof, which will be described later.

The capacitor Cst may include a first electrode CE1 and a second electrode CE2. The electrode CE1 and the electrode CE2 overlaps each other with the first interlayer insulating layer 105 therebetween and form a capacitance. In this case, the first interlayer insulating layer 105 serves as a dielectric layer of the capacitor Cst.

The first electrode CE1 may be located on the same layer as the layer on which the gate electrode 123 is located. The first electrode CE1 may be formed of the same material as the gate electrode 123, may include various conductive materials including, for example, molybdenum (Mo), aluminum (Al), copper (Cu), and titanium (Ti), and may have various layered structures (for example, a multilayer structure of Mo/Al/Mo). The second electrode CE2 may be located on the same layer as the layer on which the source electrode 125 and the drain electrode 127 are located. The second electrode CE2 may be formed of the same material as the source electrode 125 and the drain electrode 127, may include various conductive materials including, for example, molybdenum (Mo), aluminum (Al), copper (Cu), and titanium (Ti), and may have various layered structures (for example, a multilayer structure of Mo/Al/Mo).

A planarization layer 109 may be located on the thin-film transistor 120. In case that an OLED as an example of the first through third display apparatuses is located over the thin-film transistor 120, the planarization layer 109 may mostly planarize an upper portion of a protective layer that covers the thin-film transistor 120. The planarization layer 109 may include a commercial polymer such as benzocyclobutene (BCB), polyimide, hexamethyldisiloxane (HMDSO), polymethyl methacrylate (PMMA) or polystyrene (PS), a polymer derivative having a phenol-based group, an acryl-based polymer, an imide-based polymer, an acryl ether-based polymer, an amide-based polymer, a fluorine-based polymer, a p-xylene-based polymer, a vinyl alcohol-based polymer, a blend thereof, or the like within the spirit and the scope of the disclosure.

The first through third display elements may be located on the planarization layer 109. The first through third display elements may be OLEDs having the first, second, and third pixel electrodes 211, 213, and 215, an opposite electrode 230, and an intermediate layer 220 interposed between the first, second, and third pixel electrodes 211, 213, and 215 and the opposite electrode 230 and including an emission layer.

According to an embodiment, the first through third display elements may include the first, second, and third pixel electrodes 211, 213, and 215, the opposite electrode 230 corresponding to the first, second, and third pixel electrodes 211, 213, and 215, and the intermediate layer 220 interposed between the first, second, and third pixel electrodes 211, 213, and 215 and the opposite electrode 230. The intermediate layer 220 may include a first color emission layer that emits light of a wavelength belonging to a first wavelength band. For example, the first wavelength band may be 450 nm to 495 nm, and a first color may be blue. However, embodiments are not limited thereto.

The first, second, and third pixel electrodes 211, 213, and 215 of the first, second, and third display elements contact one of the source electrode 125 and the drain electrode 127 via openings (contact holes) formed in the planarization layer 109 and the like, and are electrically connected to the thin-film transistor 120. The first, second, and third pixel electrodes 211, 213, and 215 may be (semi) light-transmissive electrodes or reflective electrodes. According to an embodiment, the first, second, and third pixel electrodes 211, 213, and 215 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof, and a transparent or semi-transparent electrode layer formed on the reflective layer. The transparent or semi-transparent electrode layer may include at least one selected from the group consisting of indium tin oxide (ITO), indium zinc oxide (IZO), zinc oxide (ZnO), indium oxide (In2O3), indium gallium oxide (IGO), and aluminum zinc oxide (AZO). Each of the first, second, and third pixel electrodes 211, 213, and 215 may have a stack structure of ITO/Ag/ITO.

A pixel defining layer 110 may be located on the planarization layer 109. The pixel defining layer 110 has an opening corresponding to each subpixel to define a pixel (or an emission area). At this time, the opening is formed to expose at least a portion of a central portion of each of the first, second, and third pixel electrodes 211, 213, and 215. For example, the pixel defining layer 110 may be located between the first display element and the second display element, between the second display element and the third display element, and between the first display element and the third display element.

The pixel defining layer 110 may prevent an electric arc or the like from occurring on the edges of the first, second, and third pixel electrodes 211, 213, and 215 by increasing distances between the edges of the first, second, and third pixel electrodes 211, 213, and 215 and portions of the opposite electrode 230 on the first, second, and third pixel electrodes 211, 213, and 215. The pixel defining layer 110 may include at least one organic insulating material selected from polyimide, polyamide, acryl resin, benzocyclobutene, and a phenolic resin, and may be formed using a method such as spin coating.

The intermediate layer 220 of the first, second, and third display elements may include a low molecular weight material or a high molecular weight material. In case that the intermediate layer 220 may include a low-molecular weight material, the intermediate layer 220 may have a single- or multi-layered stack structure including at least one of a hole injection layer (HIL), a hole transport layer (HTL), an emission layer (EML), an electron transport layer (ETL) and an electron injection layer (EIL), and may be formed via vacuum deposition. In case that the intermediate layer 220 may include a high-molecular weight material, the intermediate layer 220 may have a structure including an HTL and an EML. In this case, the HTL may include poly(ethylenedioxythiophene) (PEDOT), and the emission layer may include a high-molecular weight material such as a polyphenylene vinylene (PPV)-based material or a polyfluorene-based material. The intermediate layer 220 may be formed via screen printing, inkjet printing, deposition, laser induced thermal imaging (LITI), or the like within the spirit and the scope of the disclosure. The intermediate layer 220 is not limited thereto, and may have any of various other structures.

The intermediate layer 220 may include an integrated layer covering the first, second, and third pixel electrodes 211, 213, and 215 of the first, second, and third display elements as described above. However, in some cases, the intermediate layer 220 may include a layer patterned in correspondence with each of the first through third pixel electrodes 211 through 215. In any case, the intermediate layer 220 may include a first color emission layer. The first color emission layer may cover the first through third pixel electrodes 211 through 215. In some cases, the first color emission layer may be patterned to correspond to each of the first through third pixel electrodes 211 through 215. The first color emission layer may emit light of a wavelength belonging to the first wavelength band, for example, light having a wavelength ranging from about 450 nm to about 495 nm.

The opposite electrode 230 of the first, second, and third display elements is located over a display area. For example, the opposite electrode 230 may include an integrated layer to cover the entire display area, and may be disposed over the display area. In other words, the opposite electrode 230 may be integrally formed in the first, second, and third display elements, and thus may correspond to the pixel electrodes 211, 213, and 215. In this case, the opposite electrode 230 covers the display area, but may be formed to extend to a portion of a non-display area outside the display area. As another example, the opposite electrode 230 may be formed by being patterned to correspond to each of the pixel electrodes 211, 213, and 215.

The opposite electrode 230 may be a light-transmissive electrode or a reflective electrode. According to an embodiment, the opposite electrode 230 may be a transparent or semi-transparent electrode, and may include a metal thin film having a small work function, including lithium (Li), calcium (Ca), lithium fluoride/calcium (LiF/Ca), lithium fluoride/aluminum (LiF/Al), aluminum (Al), silver (Ag), magnesium (Mg), or a compound thereof. The opposite electrode 230 may further include a transparent conductive oxide (TCO) layer including, for example, ITO, IZO, ZnO, or In₂O₃, in addition to the metal thin film.

Because the above-described OLED may be readily damaged by external moisture, external oxygen, or the like, the OLED may be covered and protected by the encapsulation layer 130. The encapsulation layer 130 may include at least one organic encapsulation layer and at least one inorganic encapsulation layer. For example, the encapsulation layer 130 may include a first inorganic encapsulation layer 131, a second inorganic encapsulation layer 133, and an organic encapsulation layer 135.

The first inorganic encapsulation layer 131 may cover the opposite electrode 230 and may include a silicon oxide, a silicon nitride, and/or silicon trioxynitride. Other layers (not shown), such as, a capping layer, may be interposed between the first inorganic encapsulation layer 131 and the opposite electrode 230. Because the first inorganic encapsulation layer 131 is formed according to a structure below the first inorganic encapsulation layer 131 and thus has a not-flat upper surface, the organic encapsulation layer 133 is formed to cover the first inorganic encapsulation layer 131 so as to provide a flat upper surface. The organic encapsulation layer 133 may include at least one material from among polyethylene terephthalate, polyethylene naphthalate, polycarbonate, polyimide, polyethylene sulfonate, polyoxymethylene, polyarylate, and hexamethyldisiloxane. The second inorganic encapsulation layer 135 may cover the organic encapsulation layer 133 and may include silicon oxide, silicon nitride, and/or silicon trioxynitride.

Even in case that cracks occur in the encapsulation layer 130 due to the above-described multi-layered structure, the encapsulation layer 130 may allow the cracks to not be connected between the first inorganic encapsulation layer 131 and the organic encapsulation layer 133 or between the organic encapsulation layer 133 and the second inorganic encapsulation layer 135. Accordingly, formation of a path via which external moisture, oxygen, or the like permeates into the OLED may be prevented or minimized.

The quantum dot layers 323 and 333, the light transmissive layer 313, the adhesive layer 30, and the first, second, and third color filter layers 311, 321, and 331 may be disposed on the encapsulation layer 130. The upper substrate 400 may be disposed on the first, second, and third color filter layers 311, 321, and 331. The first, second, and third color filter layers 311, 321, and 331 corresponding to the first, second, and third pixels PX1, PX2, and PX3, respectively, are located on a first surface of the upper substrate 400. The first surface refers to a surface (lower surface) facing the display unit 10 in case that the first, second, and third color filter layers 311, 321, and 331 are disposed over the display unit 10. The first, second, and third color filter layers 311, 321, and 331 may be located to overlap the first pixel electrode 211 or the emission layer of the first display element, the second pixel electrode 213 or the emission layer of the second display element, and the third pixel electrode 215 or the emission layer of the third display element when viewed in a direction (z-axis direction) perpendicular to the lower substrate 100 of the display unit 10 or the upper substrate 400. Accordingly, the first, second, and third color filter layers 311, 321, and 331 may serve to filter light beams emitted by the first, second, and third display elements, respectively.

First, second, and third color filter units 310, 320, and 330 may include the first, second, and third color filter layers 311, 321, and 331 located on the first surface, which is the lower surface of the upper substrate 400, and the light transmissive layer 313 located on the first color filter layer 311, the second color quantum dot layer 323 located on the second color filter layer 321, and the third color quantum dot layer 333 located on the third color filter layer 331.

In detail, the first color filter unit 310 may have the first color filter layer 311 and the light transmissive layer 313, the second color filter unit 320 may have the second color filter layer 321 and the second color quantum dot layer 323, and the third color filter unit 330 may have the third color filter layer 331 and the third color quantum dot layer 333.

The first color filter layer 311 may transmit only light having a wavelength ranging from about 450 nm to about 495 nm, the second color filter layer 321 may transmit only light having a wavelength ranging from about 495 nm to about 570 nm, and the third color filter layer 331 may transmit only light having a wavelength ranging from about 630 nm to about 780 nm. The first through third color filter layers 311 through 331 may reduce reflection of external light in the display apparatus DV.

For example, in case that external light reaches the first color filter layer 311, only light with a preset wavelength as described above is transmitted by the first color filter layer 311, and light with the other wavelengths is absorbed by the first color filter layer 311. Accordingly, only light with the preset wavelength from among external light incident upon the display apparatus DV is transmitted by the first color filter layer 311, and a portion of the transmitted light is reflected by the opposite electrode 230 or the first pixel electrode 211 below the first color filter layer 311 and is emitted back to the outside. Consequently, only a portion of external light incident upon the first pixel PX1 is reflected toward the outside, thereby reducing reflection of external light. This description is equally applicable to the second color filter layer 321 and the third color filter layer 331.

The second color quantum dot layer 323 may convert light with a wavelength belonging to the first wavelength band generated in the intermediate layer 220 of the second display element into light with a wavelength belonging to a second wavelength band. For example, in case that light having a wavelength ranging from about 450 nm to about 495 nm is generated by the intermediate layer 220 of the second display element, the second color quantum dot layer 323 may convert the light into light having a wavelength ranging from about 495 nm to about 570 nm. Accordingly, in the second pixel PX2, the light having the wavelength ranging from about 495 nm to about 570 nm is emitted to the outside.

The third color quantum dot layer 333 may convert light with a wavelength belonging to the first wavelength band generated in the intermediate layer 220 of the third display element into light with a wavelength belonging to a third wavelength band. For example, in case that light having a wavelength ranging from about 450 nm to about 495 nm is generated by the intermediate layer 220 of the third display element, the third color quantum dot layer 333 may convert the light into light having a wavelength ranging from about 630 nm to about 780 nm. Accordingly, in the third pixel PX3, the light having the wavelength ranging from about 630 nm to about 780 nm is emitted to the outside.

Each of the second color quantum dot layer 323 and the third color quantum dot layer 333 may have a shape formed by dispersing quantum dots in a resin.

Each of the quantum dots may have a particle size of several nanometers, and a wavelength of light after conversion varies according to the particle size of the quantum dot. In other words, the quantum dot may control the color of light emitted according to the particle size, and accordingly, the quantum dot may have various emission colors such as blue, red, and green. The quantum dot may have a full width of half maximum (FWHM) of an emission wavelength spectrum of about 45 nm or less, or about 40 nm or less, or about 30 nm or less, and in this range, color purity or color reproducibility may be improved. Light emitted through such quantum dots is emitted in all directions, and thus the viewing angle of the light may be improved. Moreover, the shape of the quantum dot is not particularly limited to a given shape, but may be a sphere, a pyramid, a multi-arm, or a shape of a cubic nanoparticle, a cubic nanotube, a cubic nanowire, a cubic nanofiber, or a cubic nanoplate particle. The quantum dots may include a semiconductor material such as cadmium sulfide (CdS), cadmium telluride (CdTe), zinc sulfide (ZnS), or indium phosphide (InP).

Any light-transmissive material may be used as the resin included in the second color quantum dot layer 323 and the third color quantum dot layer 333. For example, a polymer resin, such as a silicon resin, an epoxy resin, acryl, benzocyclobutene (BCB), or hexamethyldisiloxane (HMDSO), may be used as materials respectively used to form the second color quantum dot layer 323 and the third color quantum dot layer 333.

The first color filter unit 310 may include no quantum dot layers, and may include the light transmissive layer 313. For example, the first through third display elements may include the intermediate layer 220 interposed between the first through third pixel electrodes 211 through 215 and the opposite electrode 230 and including the first color emission layer that emits light of a wavelength belonging to the first wavelength band. In this case, the first pixel PX1 emits light of a wavelength belonging to the first wavelength band generated by the intermediate layer 220 to the outside without converting the wavelength. Accordingly, because the first pixel PX1 need no quantum dot layers, the first color filter unit 310 may include the light-transmissive layer 313 formed of a light-transmissive resin instead of a quantum dot layer.

The light-transmissive layer 313 may include scattering particles. The scattering particles may play a role in reducing a luminance ratio between a front side and a lateral side of light emitted by a pixel. In each pixel, light generated by a pixel electrode passes through a filter unit and is emitted to the outside, and has a luminance ratio between the front side and the lateral side of the light because the front side has a high luminance and the lateral side has a low luminance. This may cause performance degradation, such as reduction of a viewing angle or distortion of color coordinates. In the display apparatus DV according to an embodiment of the disclosure, the light transmissive layer 313 my include scattering particles, so that the light passing through the light transmissive layer 313 is scattered by the scattering particles, leading to an increase in the luminance ratio between the front side and the lateral side of the light.

According to an embodiment, a second partition wall 112 may be disposed between the light transmissive layer 313 and the second color quantum dot layer 323. A first partition wall 111 may be disposed between the light transmissive layer 313 and a third color quantum dot layer to be disposed on a left side (−x direction) of the light transmissive layer 313. The first partition wall 111 and the second partition wall 112 may include the same material as the third color quantum dot layer 333. The first partition wall 111, the second partition wall 112, and the third color quantum dot layer 333 may be formed simultaneously in the same process.

A first protective layer IL1 may be disposed on the first partition wall 111, the second partition wall 112, and the third color quantum dot layer 333, continuously over the lower substrate 100. The first protective layer IL1 may be interposed between the third color quantum dot layer 333 and the third color filter layer 331. The continuous disposition of the first protective layer IL1 over the lower substrate 100 may prevent the first partition wall 111, the second partition wall 112, and the third color quantum dot layer 333 disposed below the first protective layer IL1 from being damaged while being manufactured or while being used after the manufacture. In detail, outgas generated by the third color filter layer 331 may be prevented from damaging the quantum dots in the third color quantum dot layer 333 and thus, the quantum dots may be prevented from being unable to convert light in the first wavelength band into light in the third wavelength band.

The first protective layer IL1 may include an inorganic material, such as silicon oxide, silicon nitride, or silicon oxynitride, to block gas passage. The first protection layer IL1 may include an organic material layer including at least one material from among polyethylene terephthalate, polyethylene naphthalate, polycarbonate, polyimide, polyethylene sulfonate, polyoxymethylene, polyarylate, and hexamethyldisiloxane.

A metal layer 401 may be disposed on an upper surface and a lateral surface of each of the first partition wall 111 and the second partition wall 112. Even in case that the first partition wall 111 and the second partition wall 112 include the same material as the second color quantum dot layer 323, the respective upper surfaces and the respective lateral surfaces of the first partition wall 111 and the second partition wall 112 may be covered with the metal layer 401, thereby preventing the light emitted by the first display element and the light emitted by the second display element from intersecting each other.

The metal layer 401 may also be disposed on a lateral surface of the third color quantum dot layer 333. No metal layers may be disposed on at least a portion of an upper surface of the third color quantum dot layer 333. Because no metal layers are disposed on at least a portion of the upper surface of the third color quantum dot layer 333, the light emitted by the third display element may pass through the third color quantum dot layer 333 and may be emitted toward the third color filter layer 331.

The metal layer 401 may not be disposed on at least a portion of the first protective layer IL1 disposed between the first partition wall 111 and the second partition wall 112. The metal layer 401 may not be disposed on at least a portion of the first protective layer IL1 disposed between the second partition wall 112 and the third color quantum dot layer 333.

The light transmissive layer 313 may be disposed between the first partition wall 111 and the second partition wall 112. Because the metal layer 401 is not disposed on at least a portion of the first protective layer IL1 disposed between the first partition wall 111 and the second partition wall 112, the light emitted by the first display element may pass through the light transmissive layer 313 and may be emitted toward the first color filter layer 311.

The second color quantum dot layer 323 may be disposed between the second partition wall 112 and the third color quantum dot layer 333. Because the metal layer 401 is not disposed on at least a portion of the first protective layer IL1 disposed between the second partition wall 112 and the third color quantum dot layer 333, the light emitted by the second display element may pass through the second color quantum dot layer 323 and may be emitted toward the second color filter layer 321.

A spacer SP may be disposed on at least a portion of the third color quantum dot layer 333. In detail, the spacer SP may be disposed on at least a portion of the metal layer 401 disposed on at least a portion of the upper surface of the third color quantum dot layer 333. According to an embodiment, the spacer SP may be formed in the same process as the process for forming the light-transmissive layer 313 disposed between the first partition wall 111 and the second partition wall 112, and thus may include the same material as the light-transmissive layer 313. According to an embodiment, the spacer SP may be formed in the same process as the process for forming the second color quantum dot layer 323 disposed between the second partition wall 112 and the third color quantum dot layer 333, and thus may include the same material as the second color quantum dot layer 323.

A second protective layer IL2 may be continuously disposed on the light-transmissive layer 313 and the second color quantum dot layer 323 over the lower substrate 100. In detail, the second protective layer IL2 may be interposed between the second color quantum dot layer 323 and the second color filter layer 321. Due to the disposition of the second protective layer IL2 on the second color quantum dot layer 323, outgas generated by the second color filter layer 321 may be prevented from damaging the quantum dots in the third color quantum dot layer 323, and thus the quantum dots may be prevented from being unable to convert light in the first wavelength band into light in the second wavelength band. For example, the second protection layer IL2 may include an inorganic insulating material having a light-transmitting property, such as silicon oxide, silicon nitride, or silicon oxynitride.

The adhesive layer 30 may be disposed between the first, second, and third color filter layers 311, 321, and 331 and the second and third quantum dot layers 323 and 333 and the light-transmissive layer 313. For example, the adhesive layer 30 may be, but is not limited to, an optical clear adhesive (OCA). The adhesive layer 30 may include a filler (not shown). The filler may be interposed between the display unit 10, the second and third quantum dot layers 323 and 333, and the light transmissive layer 313 and the first, second, and third color filter layers 311, 321 and 331, and may act as a buffer against external pressure and the like within the spirit and the scope of the disclosure. The filler may be formed of an organic material (such as, methyl silicon, phenyl silicon, or polyimide), an organic sealant (such as, urethane resin, epoxy resin, or acrylic resin), or an inorganic sealant (such as, silicon), but embodiments are not limited thereto. According to a selective embodiment, the adhesive layer 30 may be omitted.

The first, second, and third color filter layers 311, 321 and 331 may be disposed on the adhesive layer 30 and the spacer SP. The first color filter layer 311 may be disposed to overlap the light transmissive layer 313 and the first pixel electrode 211. The second color filter layer 321 may be disposed to overlap the second quantum dot layer 323 and the second pixel electrode 213. The third color filter layer 331 may be disposed to overlap the third quantum dot layer 333 and the third pixel electrode 215.

Third partition walls 31 may be disposed between the first color filter layer 311 and the third color filter layer 331 and between the third color filter layer 331 and the second color filter layer 321. The third partition walls 31 define first through third color regions in separation regions between every adjacent third partition walls 31, and the first through third color regions correspond to the first through third pixels PX1 through PX3, respectively.

In case that the display unit 10, the second and third quantum dot layers 323 and 333, and the light transmissive layer 313 are bonded with the first, second, and third color filter layers 311, 321 and 331, the third partition walls 31 may be patterned to correspond to the non-emission area of the display unit 10 to serve as a light blocking layer. In other words, light may be emitted to the outside only through the first through third color regions, which are regions over the display element layer of the display unit 10 where the third partition walls 31 are not located.

These third partition walls 31 may be formed of a material (photoresist) that causes chemical changes in case that the material is irradiated with light. For example, the third partition walls 31 may include aromatic bis-azide, methacrylic acid ester, cinnamic acid ester, etc. as a negative photoresist, and may include polymethyl methacrylate, naphthynondiazide, polybten-1-sulfone, etc. as a positive photoresist. However, embodiments are not limited to thereto. Third partition walls may include a black matrix, a black pigment, a metal material, etc. to serve as a light blocking layer, and may include a reflective material, such as Al or Ag, to increase light efficiency.

The first, second, and third color filter layers 311, 321, and 331 are formed between the third partition walls 31 in correspondence with the first, second, and third pixels PX1, PX2, and PX3. For example, the first, second, and third color filter layers 311, 321, and 331 may be formed through an inkjet process, but embodiments are not limited thereto.

Referring to FIG. 6, unlike the embodiment of FIG. 5, the second color quantum dot layer 323 may be disposed between the first partition wall 111 and the second partition wall 112, and the third color quantum dot layer 333 may be disposed between the second partition wall 112 and the light transmissive layer 313. The second color filter layer 321 may be disposed to overlap the second color quantum dot layer 323, and the third color filter layer 331 may be disposed to overlap the third color quantum dot layer 333. The first color filter layer 311 may be disposed to overlap the light transmissive layer 313. In other words, a third pixel PX3 may be disposed between a first pixel PX1 and a second pixel PX2.

The first partition wall 111 and the second partition wall 112 may be formed in the same process as the process for forming the light transmissive layer 313, and may include the same material as the light transmissive layer 313. In detail, the first partition wall 111, the second partition wall 112, and the light transmissive layer 313 may include an organic material such as a polymer resin (such as, a silicon resin, an epoxy resin, acryl, benzocyclobutene (BCB), or hexamethyldisiloxane (HMDSO)). The light-transmissive layer 313 may include scattering particles.

The respective upper and lateral surfaces of the first and second partition walls 111 and 112 may be covered with the metal layer 401, and thus, even in case that the first and second partition walls 111 and 112 include the same material as the light transmissive layer 313, the light beams emitted by the second display element and the third display element may be prevented from intersecting each other. The metal layer 401 may be disposed on at least respective portions of a lateral surface and an upper surface of the light transmissive layer 313. Because the metal layer 401 is not disposed on at least a portion of the upper surface of the light transmissive layer 313, the light emitted by the first display element may pass through the light transmissive layer 313 and may be emitted toward the first color filter layer 311.

Because the metal layer 401 is not disposed on the first protective layer IL1 disposed between the first partition wall 111 and the second partition wall 112, the light emitted by the second display element may pass through the second color quantum dot layer 323 and may be emitted toward the second color filter layer 321. Because the metal layer 401 is not disposed on the first protective layer IL1 disposed between the second partition wall 112 and the light transmissive layer 313, the light emitted by the third display element may pass through the third color quantum dot layer 333 and may be emitted toward the third color filter layer 331.

A spacer SP may be disposed on at least a portion of the light transmissive layer 313. The spacer SP may be formed in the same process as the process for forming the second color quantum dot layer 323, and thus may include the same material as the second color quantum dot layer 323. According to an embodiment of the disclosure, the spacer SP may be formed in the same process as the process for forming the third color quantum dot layer 333, and thus may include the same material as the third color quantum dot layer 333.

Respective locations of the first through third pixel electrodes 211 through 213, the first through third color filter layers 311 through 331, and the light transmissive layer 313, the second color quantum dot layer 323, and the third color quantum dot layer 333 in the embodiment shown in FIG. 5 may be different from those in the embodiment shown in FIG. 6. Materials included in the first and second partition walls 111 and 112 and a material included in the spacer SP in the embodiment shown in FIG. 5 may be different from those in the embodiment shown in FIG. 6. The embodiment shown in FIG. 5 and the embodiment shown in FIG. 6 may be different from each other only in the aforementioned components, while all of the other components included in the display apparatus 1 may be the same.

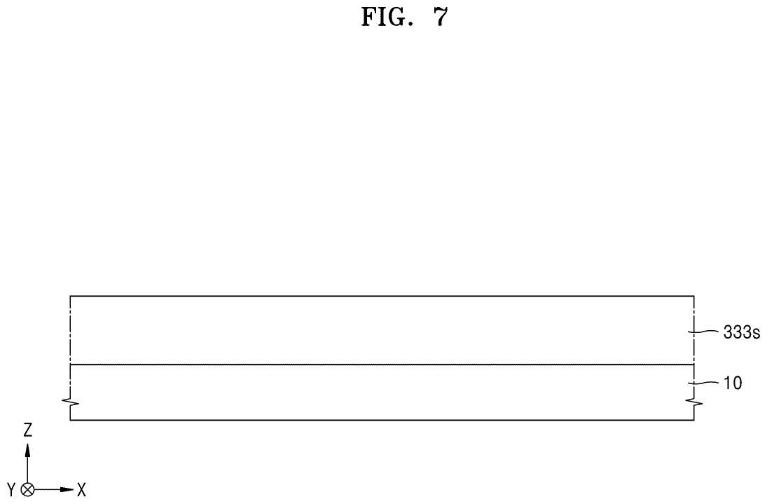

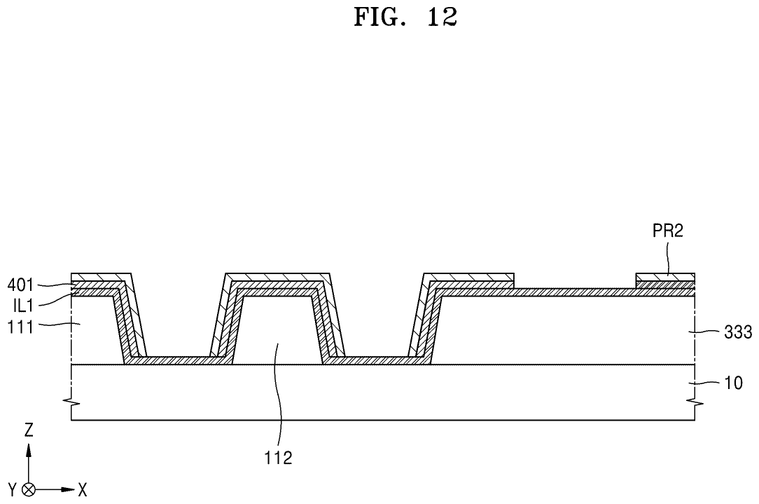

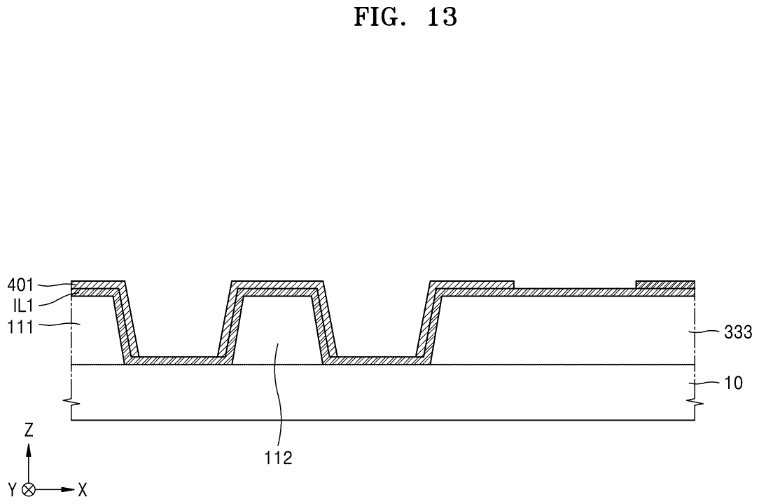

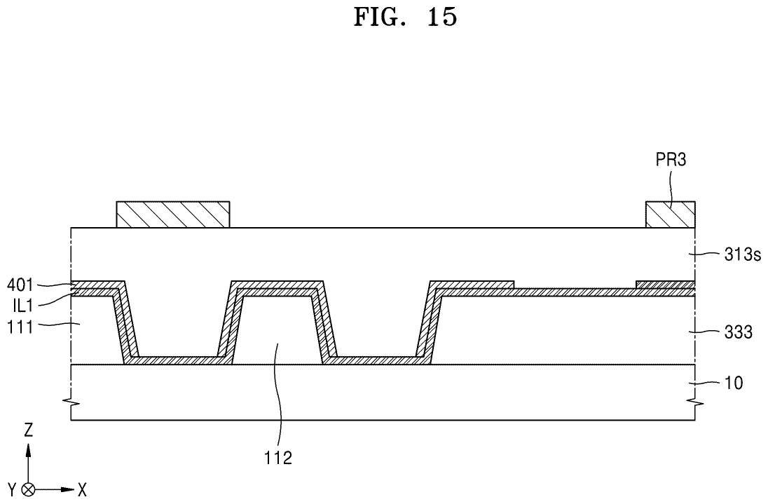

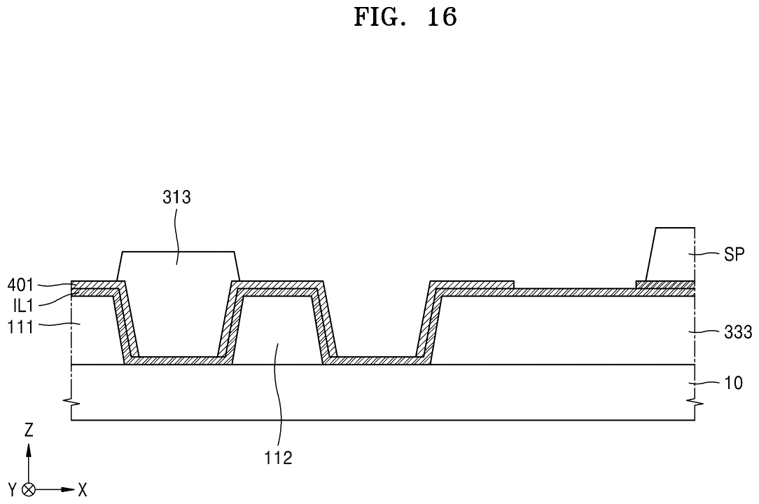

FIGS. 7 through 18 are schematic cross-sectional views schematically illustrating a method of manufacturing a display apparatus, according to an embodiment. In detail, these are schematic cross-sectional views schematically showing a manufacturing method of the first and second partition walls 111 and 112, the first and second quantum dot layers 323 and 333, the light transmissive layer 313, and the spacer SP.

Referring to FIGS. 7 through 9, the first and second partition walls 111 and 112 and the third quantum dot layer 333 may be formed. Referring to FIG. 7, a third color quantum dot layer forming material 333s may be disposed on the display unit 10. The third color quantum dot layer forming material 333s may have a shape resulted from dispersing quantum dots in a resin. Each of the quantum dots may have a particle size of several nanometers, and a wavelength of light after conversion varies according to the particle size of the quantum dot. Any light-transmissive material may be used as the resin included in the third color quantum dot layer 333. For example, the third color quantum dot layer forming material 333s may include a polymer resin, such as a silicon resin, an epoxy resin, acryl, BCB, or HMDSO.

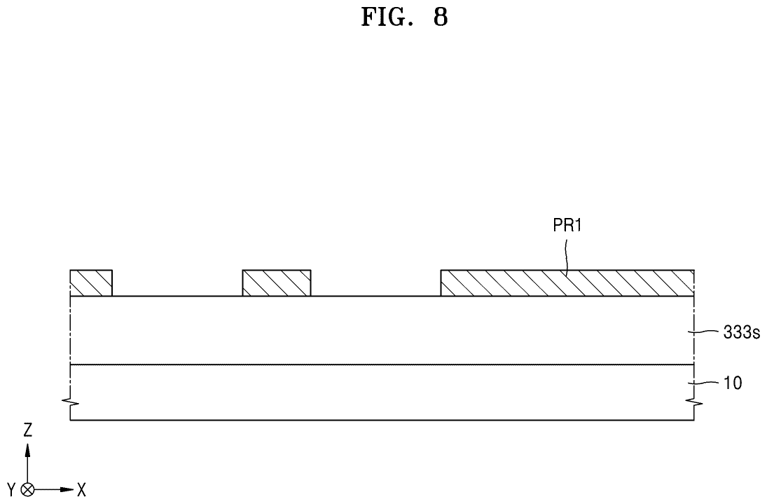

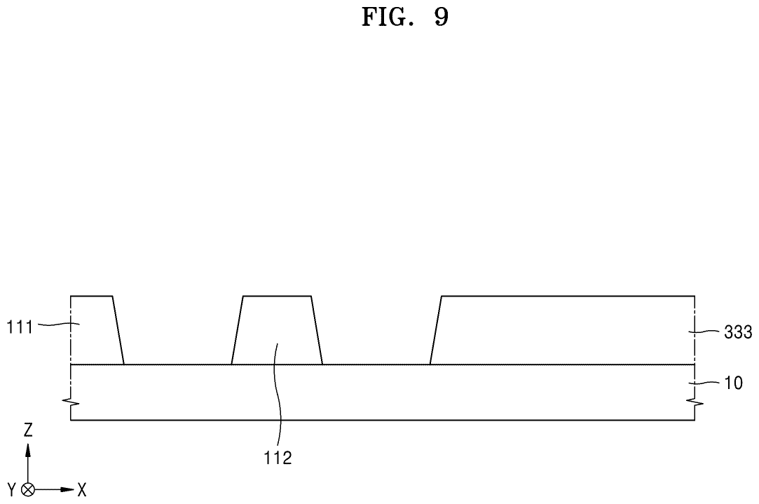

Referring to FIGS. 8 and 9, a first photoresist PR1 may be disposed on at least a portion of the third color quantum dot layer forming material 333s. At least a portion of the third color quantum dot layer forming material 333s from an upper surface where the first photoresist PR1 is not disposed may be removed through a process. The first and second partition walls 111 and 112 and the third quantum dot layer 333 may be formed by removing at least a portion of the third color quantum dot layer forming material 333s from an upper surface where the first photoresist PR1 is not disposed. The first photoresist PR1 may be removed. The first partition wall 111, the second partition wall 112, and the third color quantum dot layer 333 may be formed simultaneously in the same process and may include the same materials. By forming the first partition wall 111, the second partition wall 112, and the third color quantum dot layer 333 simultaneously in the same process, the number of masks used in the manufacturing process may be reduced, and the time required for the display apparatus manufacturing process may be reduced, and, consequently, the efficiency of a process for the display apparatus may be improved.

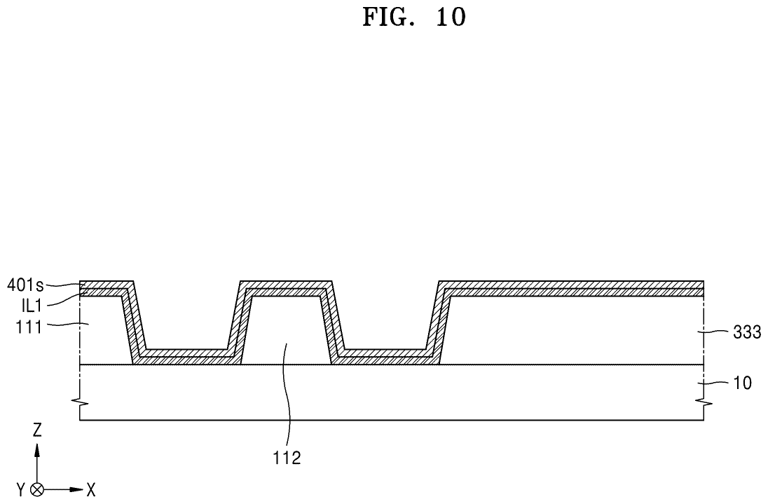

Referring to FIG. 10, a first protective layer IL1 and a metal layer forming material 401s may be disposed on the first partition wall 111, the second partition wall 112, and the third color quantum dot layer 333. The metal layer forming material 401s may be disposed on the first protective layer IL1. The first protective layer IL1 and the metal layer forming material 401s may be consecutively disposed on a substrate. The first protective layer IL1 may include an inorganic material, such as silicon oxide, silicon nitride, or silicon oxynitride, to block gas passage. The first protection layer IL1 may include an organic material layer including at least one material from among polyethylene terephthalate, polyethylene naphthalate, polycarbonate, polyimide, polyethylene sulfonate, polyoxymethylene, polyarylate, and hexamethyldisiloxane.

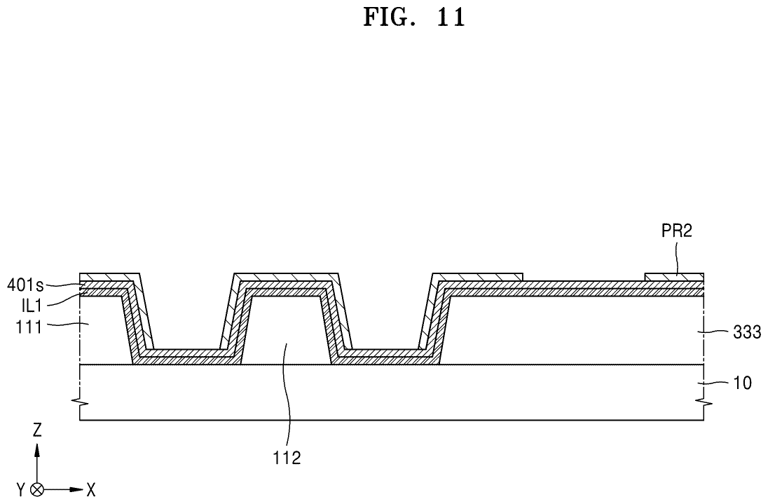

Referring to FIGS. 11 through 13, a process of forming the metal layer 401 is schematically shown. A second photoresist PR2 may be disposed on at least a portion of the metal layer forming material 401s. At least a portion of the metal layer forming material 401s from an upper surface where the second photoresist PR2 is not disposed may be removed through an etching process. Thereafter, the second photoresist PR2 may be removed. However, the disclosure is not limited thereto. According to an embodiment, the second photoresist PR2 may not be removed. In detail, the metal layer 401 may be formed by removing at least a portion of the metal layer forming material 401s through a dry etching process. The metal layer 401 may be disposed on respective upper surfaces and respective lateral surfaces of the first partition wall 111 and the second partition wall 112 and a lateral surface of the third color quantum dot layer 333.

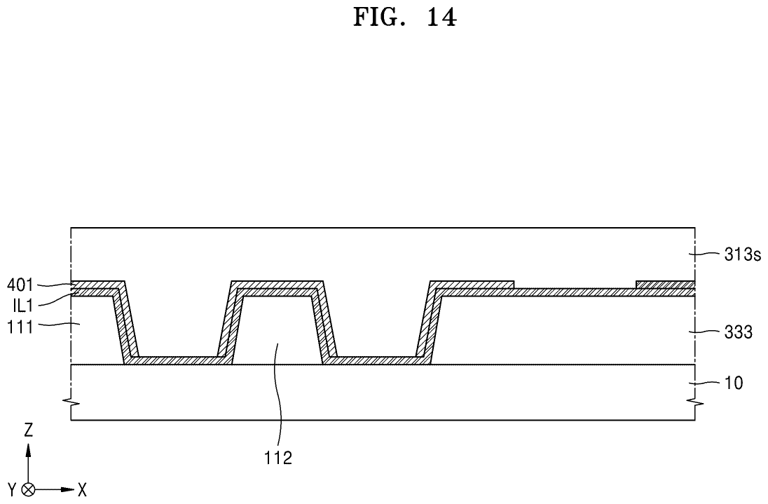

Referring to FIGS. 14 through 16, the light transmissive layer 313 and the spacer SP may be formed. A light transmissive layer forming material 313s may be continuously disposed on the metal layer 401 over the lower substrate 100. The light transmissive layer forming material 313s may include a polymer resin, such as a silicon resin, an epoxy resin, acryl, BCB, or HMDSO. The light transmissive layer forming material 313s may include scattering particles. A third photoresist PR3 may be disposed on at least a portion of the light transmissive layer forming material 313s. At least a portion of the light transmissive layer forming material 313s from an upper surface where the third photoresist PR3 is not disposed may be removed to form the light transmissive layer 313 and the spacer SP. Thereafter, the third photoresist PR3 may be removed. The light transmissive layer 313 and the spacer SP may be formed simultaneously in the same process and may include the same materials. By forming the light transmissive layer 313 and the spacer SP simultaneously in the same process, the number of masks used in the manufacturing process may be reduced, and the time required for the display apparatus manufacturing process may be reduced, and, consequently, the efficiency of a process for the display apparatus may be improved.

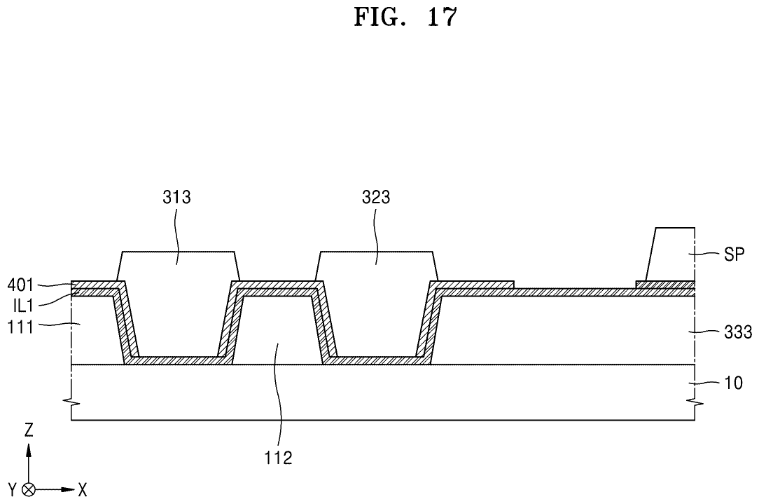

Referring to FIG. 17, the second color quantum dot layer 323 may be formed between the second partition wall 112 and the third color quantum dot layer 333. A process of forming the second color quantum dot layer 323 may be the same as the above-described process of forming the light transmissive layer 313.

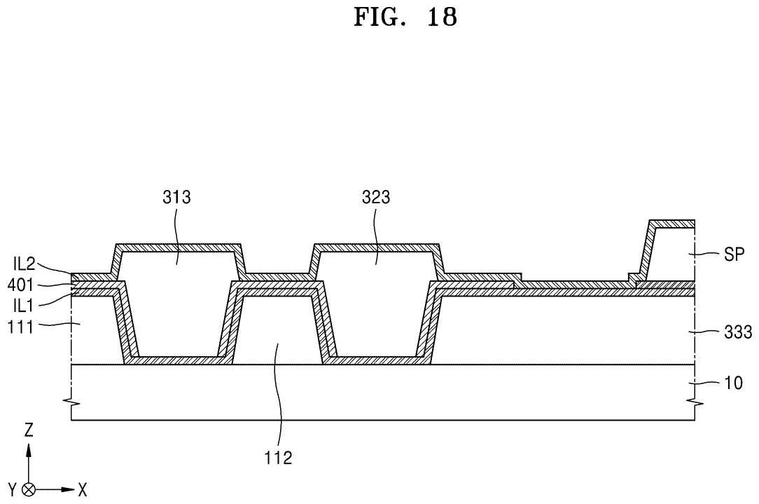

Referring to FIG. 18, a second protective layer IL2 may be formed on the light transmissive layer 313, the second color quantum dot layer 323, and the spacer SP. The second protective layer IL2 may be continuously formed on the lower substrate 100. The second protective layer IL2 may be disposed on the second color quantum dot layer 323 and the light transmissive layer 313 and protect the second color quantum dot layer 323 and the light transmissive layer 313 from outgas generated by the second and first color filter layers 321 and 311. The second protective layer IL2 may include an inorganic material, such as silicon oxide, silicon nitride, or silicon oxynitride, to block gas passage. The second protection layer IL2 may include an organic material layer including at least one material from among polyethylene terephthalate, polyethylene naphthalate, polycarbonate, polyimide, polyethylene sulfonate, polyoxymethylene, polyarylate, and hexamethyldisiloxane.

According to an embodiment as described above, a display apparatus with improved efficiency and reliability in a display apparatus manufacturing process and a manufacturing method of the display apparatus may be implemented. However, the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a first partition wall disposed on a substrate;
a first color quantum dot layer spaced apart from the first partition wall in a first direction;
a second partition wall disposed between the first partition wall and the first color quantum dot layer;
a light-transmissive layer disposed between the first partition wall and the second partition wall;
a second color quantum dot layer disposed between the second partition wall and the first color quantum dot layer; and
a metal layer disposed on respective upper surfaces and respective lateral surfaces of the first partition wall and the second partition wall and a lateral surface of the first color quantum dot layer,
wherein the first partition wall, the second partition wall, and the first color quantum dot layer each include a same material.

2. The display apparatus of claim 1, wherein the light-transmissive layer includes scattering particles.

3. The display apparatus of claim 1, further comprising:
a first protective layer disposed below the metal layer.

4. The display apparatus of claim 3, wherein the metal layer is not disposed on at least a portion of the first protective layer disposed between the first partition wall and the second partition wall, at least a portion of the first protective layer disposed between the second partition wall and the first color quantum dot layer, and at least a portion of an upper surface of the first color quantum dot layer.

5. The display apparatus of claim 1, further comprising:
a spacer disposed on at least a portion of the first color quantum dot layer.

6. The display apparatus of claim 5, wherein the spacer and the light-transmissive layer include a same material.

7. The display apparatus of claim 6, wherein the spacer and the second color quantum dot layer include a same material.

8. The display apparatus of claim 6, further comprising:
a second protective layer disposed on the light-transmissive layer, the second color quantum dot layer, and the spacer.

9. A display apparatus comprising:
a first partition wall disposed on a substrate;
a light transmissive layer spaced apart from the first partition wall in a first direction;
a second partition wall disposed between the first partition wall and the light transmissive layer;
a first color quantum dot layer disposed between the first partition wall and the second partition wall;
a second color quantum dot layer disposed between the second partition wall and the light transmissive layer; and
a metal layer disposed on respective upper surfaces and respective lateral surfaces of the first partition wall and the second partition wall and a lateral surface of the light transmissive layer,
wherein the first partition wall and the second partition wall and the light transmissive layer include a same material.

10. The display apparatus of claim 9, further comprising:
a first protective layer disposed below the metal layer.

11. The display apparatus of claim 9, further comprising:
a spacer disposed on at least a portion of the light transmissive layer.

12. The display apparatus of claim 11, wherein the spacer and the first color quantum dot layer include a same material.

13. The display apparatus of claim 11, wherein the spacer and the second color quantum dot layer include a same material.

14. A method of manufacturing a display apparatus, the method comprising:
forming a first partition wall, a second partition wall, and a first color quantum dot layer on a substrate;
forming a first protective layer on the first partition wall, the second partition wall, and the first color quantum dot layer;
forming a metal layer disposed on respective upper surfaces and respective lateral surfaces of the first partition wall and the second partition wall and a lateral surface of the first color quantum dot layer;
forming a light transmissive layer disposed between the first partition wall and the second partition wall;
forming a spacer disposed on at least a portion of the first color quantum dot layer; and
forming a second color quantum dot layer disposed between the second partition wall and the first color quantum dot layer,
wherein the light transmissive layer and the spacer are formed simultaneously.

15. The method of claim 14, wherein the light transmissive layer includes scattering particles.

16. The method of claim 14, wherein the spacer and the light transmissive layer include a same material.

17. The method of claim 14, wherein the metal layer is not disposed on at least a portion of the first protective layer disposed between the first partition wall and the second partition wall, at least a portion of the first protective layer disposed between the second partition wall and the first color quantum dot layer, and at least a portion of an upper surface of the first color quantum dot layer.

18. The method of claim 14, wherein the forming of the first partition wall, the second partition wall, and the first color quantum dot layer on the substrate comprises:
disposing, on the substrate, a first color quantum dot layer forming material;
disposing a first photoresist on at least a portion of the first color quantum dot layer forming material;
forming the first partition wall, the second partition wall, and the first color quantum dot layer by removing at least a portion of the first color quantum dot layer forming material from an upper surface where the first photoresist is not disposed; and
removing the first photoresist.

19. The method of claim 14, wherein the forming of the metal layer disposed on the respective upper surfaces and the respective lateral surfaces of the first partition wall and the second partition wall and the lateral surface of the first color quantum dot layer comprises:
continuously disposing a metal layer forming material on the first protective layer;
disposing a second photoresist on at least a portion of the metal layer forming material; and
forming a metal layer by removing at least a portion of the metal layer forming material from an upper surface where the second photoresist is not disposed.

20. The method of claim 14, wherein the forming of the light transmissive layer and the spacer comprises:
continuously disposing a light transmissive layer forming material on the metal layer;
disposing a third photoresist on at least a portion of the light transmissive layer forming material;
forming the light transmissive layer and the spacer by removing at least a portion of the light transmissive layer forming material from an upper surface where the third photoresist is not disposed; and
removing the third photoresist.
